(19) United States
(12) Patent Application Publication
(10) Pub. No.: US 2024/0356308 A1
(43) Pub. Date: Oct. 24, 2024

(54) LIGHT EMITTING APPARATUS

(71) Applicant: CANON KABUSHIKI KAISHA, Tokyo (JP)

(72) Inventors: TATSURO UCHIDA, Tokyo (JP); TAKAKO SUGA, Kanagawa (JP); TAKESHI UCHIDA, Kanagawa (JP)

(21) Appl. No.: 18/631,172

(22) Filed: Apr. 10, 2024

(30) Foreign Application Priority Data
Apr. 21, 2023 (JP) 2023-070433

(51) Int. Cl. H01S 5/42; H01S 5/042; H01S 5/183

(52) U.S. Cl. CPC H01S 5/423; H01S 5/042; H01S 5/18347; H01S 5/18311

(57) ABSTRACT

A light emitting apparatus comprises a first light emitting unit and a second light emitting unit; and a first drive wiring configured to drive the first light emitting unit and a second drive wiring configured to drive the second light emitting unit. A plurality of light emitting elements having mesa structure is arranged in the first light emitting unit and the second light emitting unit. The first drive wiring is in electrical contact with an upper surface of the mesa structure in the first light emitting unit. The first drive wiring extends above the upper surface of the mesa structure in the second light emitting unit. The upper surface of the mesa structure in the second light emitting unit and the first drive wiring are electrically insulated by an insulating film.

### BACKGROUND

### Field

The present invention relates to a light emitting apparatus.

### Description of the Related Art

A light emitting apparatus, in particular, a Vertical Cavity Surface Emitting Laser (VCSEL) array element, in which VCSELs are arranged in a two-dimensional array, is known. The VCSEL array element is developed as a light source for a Light Detection and Ranging (LiDAR) sensor or a 3 Dimension (3D) sensor. In particular, the VCSEL array element having an increased output is required in order to improve the performance of distance measurement (sensitivity, resolution, enlarged distance measurement range, etc.). In addition, downsizing of the element is also required. To achieve this requirement, it is preferable to arrange VCSELs, each having a wide light emission diameter, in high density (narrow pitch).

For a VCSEL array element applied for a light source for LiDAR, a flash method is known which causes all the VCSELs included in the array, in which VCSEL elements are two-dimensionally arranged, to simultaneously emit light to perform distance measurement for a large area. In addition, a sequential flash method is known which causes each of a plurality of light emitting units, in which the VCSEL array is divided into a plurality of light emitting units each including a plurality of light emitting elements, to sequentially emit light. For example, a VCSEL array element is divided, as for a light source for sequential flash, into ten light emitting units each including a plurality of light emitting elements. The distance measurement performance is improved if the optical power density of a single light emitting unit can be equalized to the optical power density of whole of the VCSEL array element. In Japanese Patent Laid-Open No. 2022-165805, it is described that size of the light emitting apparatus is reduced by arranging electrodes on the short side of a substrate.

In order to make each of the light emitting units, in which a plurality of light emitting elements are arranged, emit light individually, drive wirings that cause respective light emitting units to emit light are required. However, there is only a limited space for disposing wirings for driving in the light emitting unit. In addition, a high current injection value is required in order to cause the light emitting unit including a plurality of light emitting elements to emit light. However, in order to avoid disconnection of the drive wiring due to electromigration, it is necessary to increase the width of the wiring as much as possible to increase the limiting current density.

### SUMMARY

The present invention provides an advantageous technology for driving a light emitting apparatus including a plurality of light emitting units, in which a plurality of light emitting elements are arranged, to emit light.

In consideration of the aforementioned problems, a light emitting apparatus according to a first aspect of the present invention includes a first light emitting unit and a second light emitting unit, and a first drive wiring configured to drive the first light emitting unit and a second drive wiring configured to drive the second light emitting unit, and a plurality of light emitting elements having mesa structure of a compound semiconductor is arranged in the first light emitting unit and the second light emitting unit, the first drive wiring is in electrical contact with an upper surface of the mesa structure of the compound semiconductor in the first light emitting unit, the second drive wiring is in electrical contact with an upper surface of the mesa structure of the compound semiconductor in the second light emitting unit, the first drive wiring extends above the upper surface of the mesa structure of the compound semiconductor in the second light emitting unit, and the upper surface of the mesa structure of the compound semiconductor in the second light emitting unit and the first drive wiring are electrically insulated by an insulating film arranged between the upper surface of the mesa structure of the compound semiconductor in the second light emitting unit and the first drive wiring.

Further features of the present invention will become apparent from the following description of exemplary embodiments (with reference to the attached drawings).

### BRIEF DESCRIPTION OF THE DRAWINGS

FIG. 1A and FIG. 1B are schematic plan diagrams for explaining a configuration of a light emitting apparatus according to a first embodiment;

FIG. 2 is a schematic cross-sectional diagram taken along A-A′ for explaining a configuration of the light emitting apparatus according to the first embodiment;

FIG. 3 is a schematic cross-sectional diagram taken along B-B′ for explaining a configuration of the light emitting apparatus according to the first embodiment;

FIG. 4A, FIG. 4B and FIG. 4C are schematic plan diagrams for explaining a method of manufacturing the light emitting apparatus according to the first embodiment;

FIG. 5 is a schematic cross-sectional diagram for explaining a configuration of a light emitting apparatus according to a second embodiment;

FIG. 6A and FIG. 6B are schematic plan diagrams for explaining a configuration of the light emitting apparatus according to the second embodiment;

FIG. 7A and FIG. 7B are schematic plan diagrams for explaining a configuration of a light emitting apparatus according to a third embodiment;

FIG. 8 is a schematic cross-sectional diagram taken along A-A′ for explaining a configuration of the light emitting apparatus according to the third embodiment;

FIG. 9A and FIG. 9B are schematic plan diagrams for explaining a configuration of the light emitting apparatus according to the third embodiment;

FIG. 10A and FIG. 10B are schematic plan diagrams for explaining a configuration of the light emitting apparatus according to the third embodiment;

FIG. 11A and FIG. 11B are schematic plan diagrams for explaining a configuration of a light emitting apparatus according to a fourth embodiment; and

FIG. 12A and FIG. 12B are schematic plan diagrams for explaining a configuration of the light emitting apparatus according to the fourth embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate.

Furthermore, in the attached drawings, the same reference numerals are given to the same or similar configurations, and redundant description thereof is omitted.

Furthermore, each drawing is presented merely for the purpose of explaining a structure or a configuration, and each of the dimensions of illustrated members do not necessarily reflect actual dimensions.

In the following embodiments, a Vertical Cavity Surface Emitting Laser (VCSEL) array element including a plurality of VCSEL elements will be described as an example of a light emitting apparatus to which the present invention can be applied. The present invention can also be applied to a light emitting apparatus including a plurality of light emitting units in which a plurality of light emitting elements having mesa structure such as Light Emitting Diodes (LEDs) is arranged. In the following, an embodiment of the technology of the present disclosure will be described.

### First Embodiment

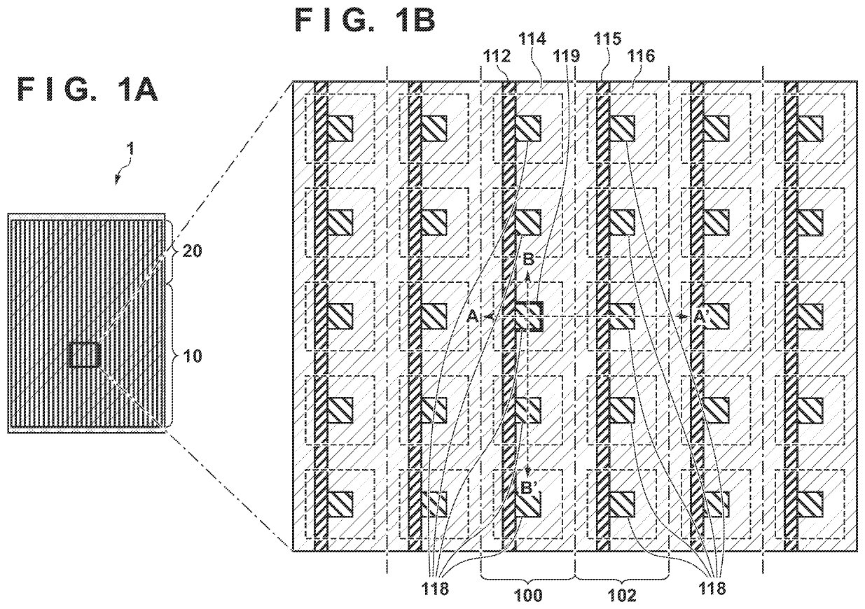

In FIG. 1A and FIG. 1B, schematic plan diagrams are illustrated for explaining a configuration of a light emitting apparatus 1 according to a first embodiment. FIG. 1A is a schematic plan diagram of the entire light emitting apparatus 1 in which VCSEL elements are arranged in an array as light emitting elements, seen from the side where the light is emitted. A light emitting apparatus 1 includes a VCSEL element unit 10 in which VCSEL elements are arranged, and a terminal pad unit 20 in which a terminal pad is arranged. The light emitting apparatus of the present embodiment includes a plurality of VCSEL elements having square mesa structure of a compound semiconductor is arranged in a two-dimensional array at constant intervals. As illustrated in FIG. 1A in a manner delimited by lines, a plurality of VCSEL elements arranged in a column are collectively defined as a single light emitting unit. Assuming that the direction from the terminal pad unit 20 to the VCSEL element unit 10 in FIG. 1A is the vertical direction of the light emitting apparatus 1, the light emitting apparatus 1 is vertically divided into 32 columns of light emitting units. And the VCSEL elements are arranged alongside each other in the vertical column direction (first direction) in the light emitting unit.

FIG. 1B is a plan diagram schematically illustrating a part of the VCSEL element unit 10 in an enlarged manner. The VCSEL element unit 10 is divided into a plurality of light emitting units as indicated by dot and dash lines. In the present embodiment, the VCSEL elements are arranged in a column surrounded by dot and dash lines, and the VCSEL elements arranged in each light emitting unit can be simultaneously driven by the drive wirings for each light emitting unit to control light emission. The mesa structure part of the VCSEL element is a region indicated by dashed lines. The region corresponds to a single VCSEL element. The present embodiment will be explained by taking an example of a light emitting apparatus in which 960 VCSEL elements are arranged in a 32×30 two-dimensional array with 32 vertical columns and 30 horizontal rows at a pitch of 30 μm.

Structures of the first light emitting unit 100 and the second light emitting unit 102 will be described, referring to FIG. 1B. In the first light emitting unit 100, light is emitted from a light output portion 118. The light output portion 118 is covered by an insulating film that transmits the light. Similarly, the light output portion 118 is also provided in the second light emitting unit 102. A first drive wiring 114 configured to supply current to the first light emitting unit 100 is arranged.

The first drive wiring 114 is a wiring configured to drive the first light emitting unit 100. Similarly, the second drive wiring 116 is a wiring configured to drive the second light emitting unit 102.

In FIG. 1B, an example is illustrated in which openings 119 for electrically contacting the first drive wiring to an upper surface of a semiconductor layer 108 in the mesa structure are provided around the light output portion 118 located at the intersection of lines A-A′ and B-B′. Here, the upper surface of a semiconductor layer 108 in the mesa structure is a surface of the semiconductor layer 108 in the mesa structure on a side where the light is emitted from the first light emitting unit 100 and the second light emitting unit 102. The openings 119 are provided on three sides around the light output portion 118. The openings 119 are located below the first drive wiring and thus the openings 119 are not exposed. Although openings are similarly provided around other light output portions 118, they are omitted in the drawing.

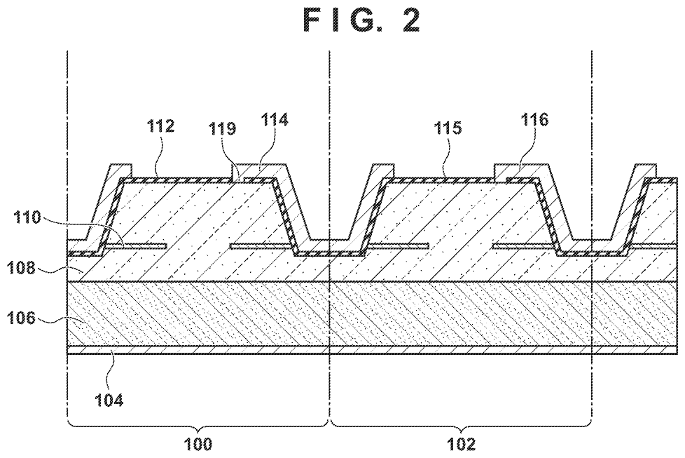

FIG. 2 is a diagram schematically illustrating a cross section taken along the line A-A′ in FIG. 1A. Here, the first light emitting unit 100 and the second light emitting unit 102 arranged alongside each other, among the 32 columns of light emitting units, will be described.

As illustrated in FIG. 2, a second insulating film 115 is arranged between the first drive wiring 114 of the first light emitting unit and an upper surface of a semiconductor layer 108 in the mesa structure in the second light emitting unit 102, opposite to the side of the compound semiconductor substrate 106 where a common electrode 104 is arranged. The second insulating film 115 electrically insulates the drive wiring 114, which supplies current to the first light emitting unit 100, from the second light emitting unit 102. As such, the first light emitting unit 100 and the second light emitting unit 102 are electrically insulated from each other by the second insulating film 115. Here, the two light emitting units are referred to as the first light emitting unit 100 and the second light emitting unit 102 for the sake of convenience. Although the light output portion, the drive wiring, and the insulating film and the like are similarly provided to the other light emitting units 100, 102 arranged alongside in a direction intersecting the first direction with respect to the first light emitting unit 100 and the second light emitting unit 102, description thereof is omitted here.

VCSEL elements having mesa structure is arranged in the first light emitting unit 100 and the second light emitting unit 102. A common electrode 104 configured to commonly supply current to the plurality of light emitting units is provided on the side of the compound semiconductor substrate 106 opposite to the side on which the first drive wiring 114 and the second drive wiring 116 are arranged. The semiconductor layer 108 in the mesa structure forming the VCSEL element is formed on the compound semiconductor substrate 106. Oxidized confinement structure 110 is provided to the semiconductor layer 108. A region surrounded by the oxidized confinement structure 110 corresponds to the light emitting region that emits light.

The first insulating film 112 functions as a light output portion configure to cause the light emitted from the light emitting region to emit. In order to successfully function as a light output portion, the insulating film may preferably have a thickness of λ/2n thick (λ: oscillation wavelength, n: refractive index of the insulating film). The first drive wiring 114 is in electrical contact, at the opening 119, with the upper surface of the semiconductor layer 108 of the mesa structure. The first drive wiring 114 may be arranged extending above the mesa structure of the second light emitting unit 102. However, the second insulating film 115 is located between the first drive wiring 114 and the upper surface of the semiconductor layer 108 of the mesa structure in the second light emitting unit 102, and thus the upper surface of the mesa structure in the second light emitting unit 102 and the first drive wiring 114 are electrically insulated by the second insulating film 115. By employing such a configuration, the first drive wiring 114 can be arranged extending across between the VCSEL elements having the mesa structure, whereby a large cross-sectional area for the drive wiring can be secured.

In addition, the openings 119 are arranged around the first insulating film 112 of the light output portion 118 and therefore the first drive wiring is in electrical contact with the upper surface of the mesa structure across the periphery of the light output portion 118. For example, in the case of a light emitting apparatus in which VCSEL elements each having a length of the side of the mesa structure being 20 μm and a length of the side of the light emitting region being 6 μm are arranged in a two-dimensional array, carriers injected from the first drive wiring 114 spread across the entire region of the light emitting region having a length of the side being 6 μm. Therefore, the light can be emitted from the entire region of light emitting region. In this case, as illustrated in FIG. 2, the tip (mesa center side) of the first drive wiring 114 is preferably positioned overlapping with the tip (mesa center side) of the oxidized confinement structure 110 in a planar view to prevent the first drive wiring 114 from blocking the emitting light from the light emitting region. Alternatively, the tip of the oxidized confinement structure 110 may be longer than the tip of the first drive wiring 114 by about 0 to 2 μm toward the mesa center side.

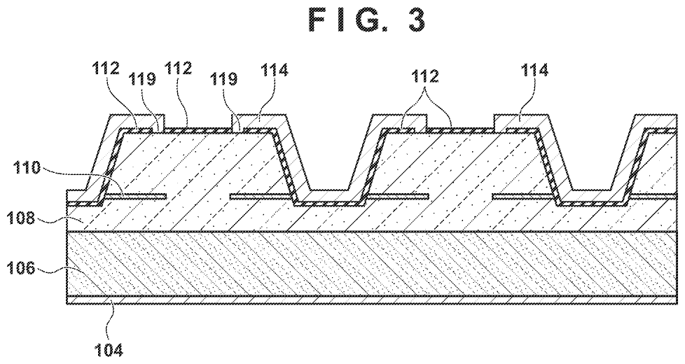

FIG. 3 is a diagram schematically illustrating a cross section taken along the line B-B′ in FIG. 1B. FIG. 3 is a diagram schematically illustrating a cross section of the first light emitting unit 100 in FIG. 2, taken along a direction in which a plurality of VCSEL elements are arranged alongside in a vertical column. The openings 119 formed in the first insulating film 112 illustrated in FIG. 1B are also illustrated in FIG. 2 and FIG. 3. The first drive wiring 114 of the first light emitting unit 100 is in electrical contact with the upper surface of the semiconductor layer 108 in the mesa structure via the openings 119 formed in the first insulating film 112, and thus carriers can be injected.

Next, a method of manufacturing the light emitting apparatus according to the present embodiment will be described, taking an example of a VCSEL element that emits light in a 940 nm band. First, an n-type GaAs substrate is prepared as a compound semiconductor substrate.

A resonator layer including an n-type GaAs/AlGaAs Distributed Bragg Reflector (DBR) and a Multi Quantum Well (MQW) is formed on the n-type GaAs substrate. Next, a selective oxidation layer p-Al0.98GaAs and a p-type GaAs/AlGaAs DBR are formed. The semiconductor layer may be formed by epitaxial growth in the order of the resonator layer and the selective oxidation layer. Subsequently, a mesa structure is formed by using photolithography technology and etching technology.

Next, the selective oxidation layer p-Al0.98GaAs is selectively oxidized by water vapor from the mesa sidewall to form the oxidized confinement structure 110. Subsequently, a first insulating film 112 is formed covering the mesa structure. Subsequently, the openings 119 are formed in the first insulating film 112 by using photolithography technology and etching technology. Next, the first drive wiring 114 and the second drive wiring 116 are formed using a lift-off technology by which a resist is arranged at a position where metal is not to be arranged, and the metal is deposited by vapor deposition, and then the resist is removed. Subsequently, after the n-GaAs substrate is polished, the common electrode 104 is formed on the back surface of the substrate.

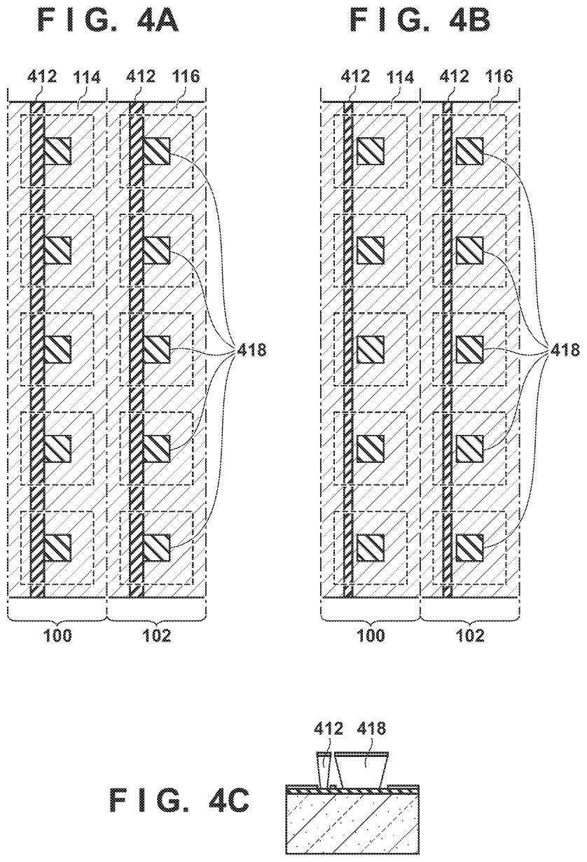

Referring to the plan diagrams illustrated in FIG. 4A, FIG. 4B and FIG. 4C, a light emitting apparatus will be described, in which the VCSEL element are arranged in an array such that the vertical column length of the VCSEL element in the light emitting unit is 300 μm or more and the closest distance between the first drive wiring 114 and the second drive wiring 116 is 10 μm or less. The first drive wiring 114 and the second drive wiring 116 are formed by using photolithography technology, vacuum deposition technology, and lift-off technology. In these steps, the lift-off resist patterns (412 and 418) to be formed by using photolithography technology may be formed into a pattern shape illustrated in FIG. 4A. In other words, as for the planar pattern of the lift-off resist, an integrated pattern is employed in which the lift-off resist pattern 418 for forming the light output portion 118 and the lift-off resist pattern 412 for separating adjacent drive wirings are connected together. The foregoing allows for stably maintaining the lift-off resist pattern shape during the vapor deposition step. The output portion shape can be formed in a desired shape by integrating the lift-off resist patterns 412 and 418.

On the other hand, as illustrated in FIG. 4B, a planar pattern having a large aspect ratio (10 μm or less in horizontal length and 300 μm or more in vertical length) is formed with a resist thickness of 1 μm or more in order to separate adjacent drive wirings. Cross-sectional structure of the lift-off resist patterns 412 and 418 of FIG. 4B are illustrated in FIG. 4C. In this example, the lift-off resist patterns 412 and 418 are not connected to each other. In such a case, heat and stress applied to the resist during the deposition step may cause the planar pattern to fluctuate, fall, or break. As a result, a drive wiring may be formed on the light output portion which may block the exiting light. On the other hand, a pattern illustrated in FIG. 4A is employed, in which the exposed first insulating film 112 serving as the light output portion 118 and the first insulating film 112 exposed for separating adjacent drive wirings are connected to each other. Accordingly, the resist pattern is integrated such that the resist pattern forming the light output portion supports the resist pattern having a large aspect ratio for separating adjacent drive wirings. Since drive wirings can be stably formed in the aforementioned manner, it is possible to drive the light emitting unit without blocking the light output portion.

Here, the first insulating film 112 is formed of a dielectric insulating film including any of silicon oxide, silicon nitride, silicon oxynitride, amorphous silicon, aluminum oxide, or the like.

In addition, the first drive wiring 114 and the second drive wiring 116 may be formed of any combination of gold and titanium, gold and platinum and titanium, gold and titanium and copper and gold and titanium.

In order to particularly increase the limit value of the current density, it is preferable to employ a composition mainly using copper. In addition, in order to improve the optical power density of the light emitting elements, it is preferable to densely arrange light emitting elements. In order to achieve this, the first drive wiring and the second drive wiring may be spaced apart from each other by a distance equal to or less than a quarter of an interval (pitch) at which the plurality of light emitting elements are arranged. Although a stacked member that can be formed on the first insulating film 112 is not described in the present embodiment, a reflectance-adjusting layer, an anti-reflection film, or the like may be formed. In addition, although the terminal pad unit 20 is provided at a single location for each of the 32 columns of light emitting units in the present embodiment, terminal pads may be provided at two or more locations.

### Second Embodiment

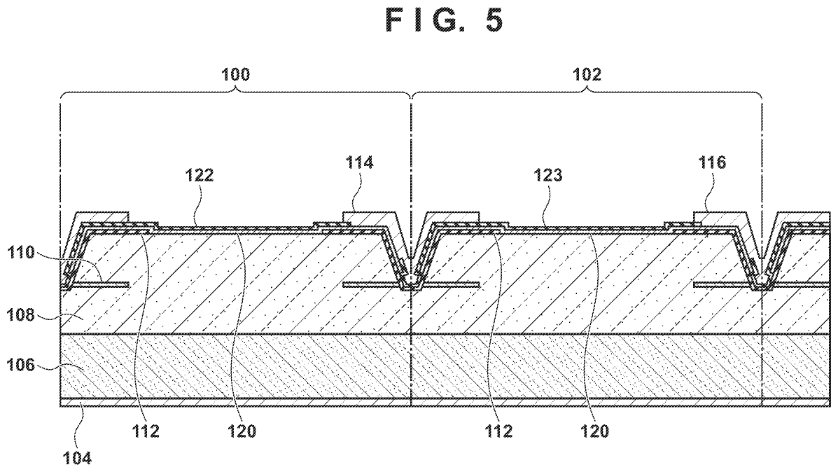

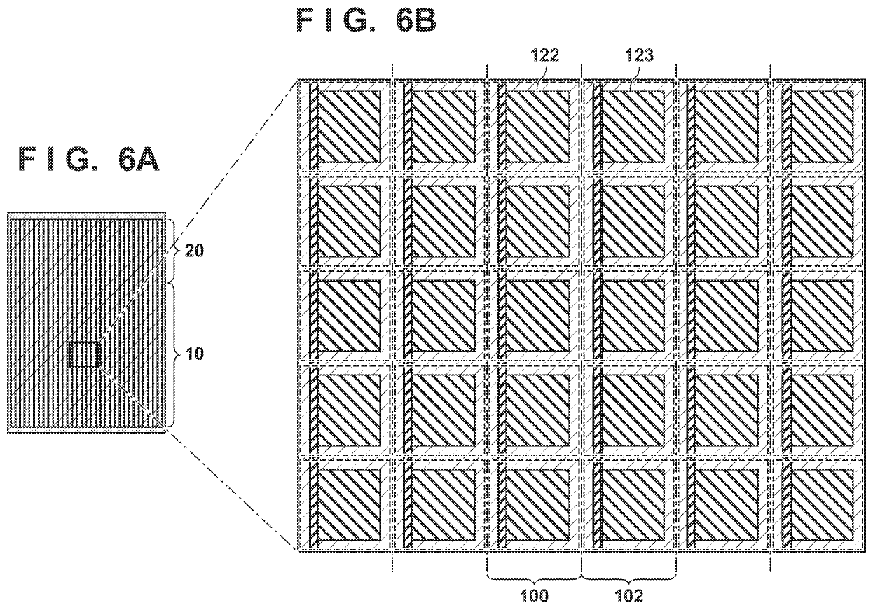

Next, a second embodiment will be described, referring to FIG. 5, FIG. 6A and FIG. 6B. In the second embodiment, a light emitting apparatus including VCSEL elements being arranged in a two-dimensional array, in which the VCSEL elements each have a length of the side of the mesa structure of the VCSEL element being enlarged to 38 μm and a length of the side of the light emitting region being 30 μm in order to further increase the optical power density, will be exemplarily described. In a case where a length of the side of the light emitting region is extended to 30 μm, carriers are concentrated in the outer peripheral of the light emitting unit when the carriers are injected to the light emitting unit, and as a result, the light may be emitted in a ring shape in which light emitting pattern concentrates around the light output portion. In the present embodiment, therefore, a transparent conductive film 120 is arranged covering at least the upper surface of the mesa structure, as illustrated in FIG. 5. By employing the aforementioned configuration, the injected carriers can diffuse within the transparent conductive film 120, and the diffused carriers may entirely spread across the light emitting unit surrounded by the oxidized confinement structure 110, and thus the light can be uniformly emitted from the entire region of the light emitting unit.

In the present embodiment, when the light emitting units are formed with high density and with a narrow pitch in order to increase the optical power density, a region for disposing drive wirings may be limited. A configuration that may allow for disposing drive wirings having a larger cross-sectional area in order to supply sufficient current even in such a situation will be described.

Schematic plan diagrams of the present embodiment are illustrated in in FIG. 6A and FIG. 6B. FIG. 6A and FIG. 6B are diagrams seen from the side from which the light is emitted. Here, the plan diagrams used for explaining other embodiments are also diagrams seen from the side from which the light is emitted. As illustrated in FIG. 6B, a third insulating film 122 and the fourth insulating film 123 are exposed in the present embodiment, instead of the first insulating film 112 described in the first embodiment. Other than this point, it is similar to those of the plan diagram 1B of the first embodiment described above, and therefore description thereof will be omitted. In addition, in the following description, configurations and steps that are similar to those of the first embodiment will be omitted.

A schematic cross-sectional diagram for explaining a configuration of the light emitting apparatus according to the present embodiment in which the VCSEL elements are arranged is illustrated in FIG. 5. As illustrated in FIG. 5, the transparent conductive film 120 is stacked at the upper surface of the semiconductor layer 108 in each of the mesa structure, and the transparent conductive film 120 and the upper surface of the semiconductor layer 108 in the mesa structure is in electrical contact with each other via an opening formed in the first insulating film 112.

As illustrated in FIG. 5, the first drive wiring 114 is also in electrical contact with the transparent conductive film 120, which is in electrical contact with the upper surface of the semiconductor layer 108 in the mesa structure of the first light emitting unit 100. On the other hand, a fourth insulating film 123 is located between the first drive wiring 114 and the transparent conductive film 120 that is in electrical contact with the upper surface of the semiconductor layer 108 in the mesa structure of the second light emitting unit 102. Accordingly, the first drive wiring 114 and the transparent conductive film 120 that is in electrical contact with the upper surface of the semiconductor layer 108 in the mesa structure of the second light emitting unit 102 are not in electrical contact with each other. In addition, the first drive wiring 114 may be arranged extending across from the first light emitting unit 100 to the second light emitting unit 102.

The cross-sectional area (wiring width in FIG. 5) of the first drive wiring 114 can be expanded by employing the aforementioned configuration. When the third insulating film 122, the fourth insulating film 123 and the transparent conductive film 120 are formed above the light output portion, in order to improve light-transmitting, it is preferable to form the thicknesses by considering the refractive index. In other words, in consideration of each refractive index of the insulating film and the conductive film, the optical path length depending on the thicknesses of the insulating film and the conductive film may be set to an integral multiple of λ/2 (λ: oscillation wavelength).

A manufacturing method will be described. After an opening is formed in the first insulating film 112 described in the first embodiment, the transparent conductive film 120 is formed. Subsequently, the transparent conductive film 120 is formed, by using photolithography technology and etching technology, at least on the mesa structure, and also disconnected at the boundary between the first light emitting unit 100 and the second light emitting unit 102. Subsequently, the third insulating film 122 and the fourth insulating film 123 are formed covering the mesa structure. Subsequently, an opening is formed in a part of the third insulating film 122 and the fourth insulating film 123 by using photolithography technology and etching technology, and thus the transparent conductive film 120 is exposed. Next, the first drive wiring 114 and the second drive wiring 116 are formed by using photolithography technology, vacuum deposition technology, and lift-off technology. Subsequently, after the n-GaAs substrate that is a compound semiconductor is polished, the common electrode 104 is formed on the back surface of the substrate.

Here, the insulating film may be formed of a dielectric insulating film including any of silicon oxide, silicon nitride, silicon oxynitride, amorphous silicon, aluminum oxide, or the like. In addition, the first drive wiring 114 and the second drive wiring 116 may be formed of any combination of gold and titanium, gold and platinum and titanium, gold and titanium and copper and gold and titanium. In order to particularly increase the limiting current density, it is preferable to employ a composition mainly using copper. In addition, the transparent conductive film 120 is formed of an oxide semiconductor including any of indium tin oxide (ITO), indium oxide, tin oxide, zinc oxide, indium gallium zinc oxide, or the like.

Although a stacked member to be formed on the third insulating film 122 and the fourth insulating film 123 is not described in the present embodiment, a reflectance-adjusting layer, an anti-reflection film, or the like may be formed.

### Third Embodiment

In the third embodiment, a case will be described in which two vertical columns of VCSEL elements are collectively defined as a single light emitting unit, and each light emitting unit is individually driven. In the following description, configurations and steps that are similar to those of the first and the second embodiments will be omitted.

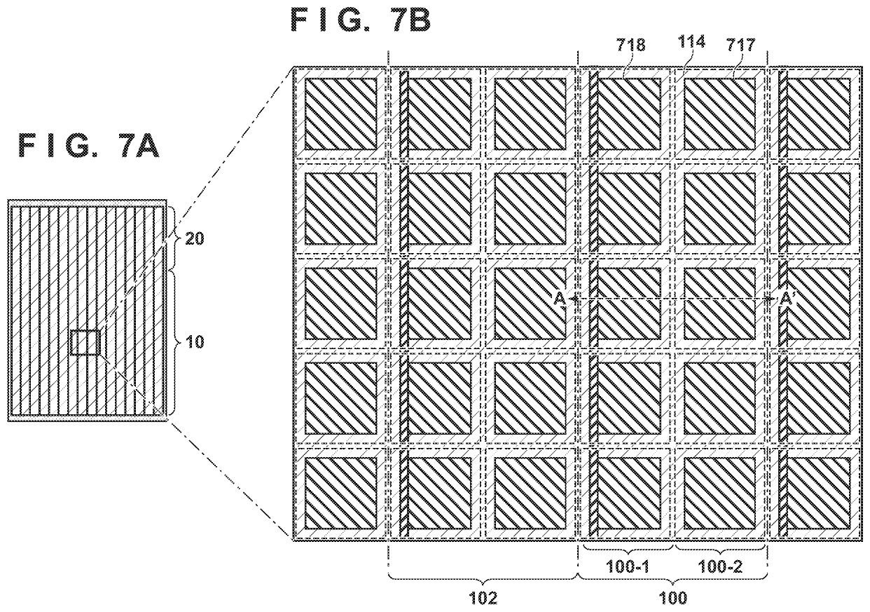

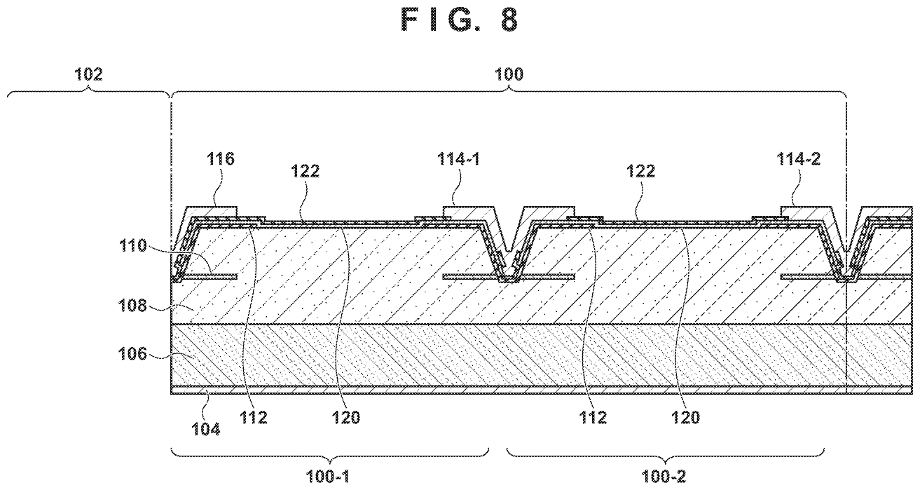

As illustrated in FIG. 7A, FIG. 7B and FIG. 8, the first light emitting unit 100 of the third embodiment includes a plurality of light output portions 717 annularly surrounded by the first drive wiring 114, and a light output portion in which a part of the first drive wiring 114 is disconnected and the plurality of light output portions 718 are connected by the insulating film. In the present embodiment, the two columns of light emitting units included in the first light emitting unit 100 will be respectively referred to as a first light emitting unit 100-1 and a first light emitting unit 100-2. The first light emitting unit 100-1 and the first light emitting unit 100-2 are driven by the first drive wiring 114.

FIG. 8 illustrates a cross-sectional diagram taken along the line A-A′ illustrated in FIG. 7B. In the present embodiment, the transparent conductive film 120 is stacked over the upper surface of the semiconductor layer 108, and the transparent conductive film 120 and the upper surface of the semiconductor layer 108 of the first light emitting unit 100-1 are in electrical contact with each other via an opening formed in the first insulating film 112.

In addition, the third insulating film 122 is stacked on the transparent conductive film 120, and the first drive wiring 114-1 is in electrical contact with the transparent conductive film 120 via an opening formed in the third insulating film 122. In addition, the first drive wiring 114-1 is similarly in electrical contact with the upper surface of the semiconductor layer 108 of the first light emitting unit 100-2 via the opening formed in the third insulating film 122 and the opening formed in the first insulating film 112. The first drive wiring 114-2 is also in electrical contact with the upper surface of the semiconductor layer 108 of the first light emitting unit 100-2 via the opening formed in the third insulating film 122 and the opening formed in the first insulating film 112.

Here, the drive wiring and the upper surface of the semiconductor layer 108 in the mesa structure may be brought into electrical contact with each other by providing openings around the light output portion similarly to the first embodiment. In such a case, the light output portions 718 connected by the insulating film may be provided with openings except for a part of the periphery around the light output portion. The openings 119 may be provided surrounding a part of the light output portion, as illustrated in FIG. 1B. As the periphery of the light output portion 717 is surrounded by the drive wiring, the openings may be provided along the entire periphery of the light output portion 717 such that the drive wiring and the upper surface of the semiconductor layer 108 in the mesa structure are brought into electrical contact with each other.

The second drive wiring 116 and the upper surface of the semiconductor layer 108 of the first light emitting unit 100-1 are electrically insulated by the third insulating film 122 located therebetween, and therefore the first light emitting unit 100 is not driven by the second drive wiring 116. In addition, the third insulating film 122 is arranged between the first drive wiring 114-2 and the upper surface of the semiconductor layer 108 of an adjacent light emitting unit (not illustrated), and thus the adjacent light emitting unit is not driven. The two columns of the first light emitting unit 100, namely the first light emitting units 100-1 and 100-2 are thus driven by the two first drive wirings 114-1 and 114-2. The two first drive wirings 114-1 and 114-2 illustrated in FIG. 8 are electrically connected to each other.

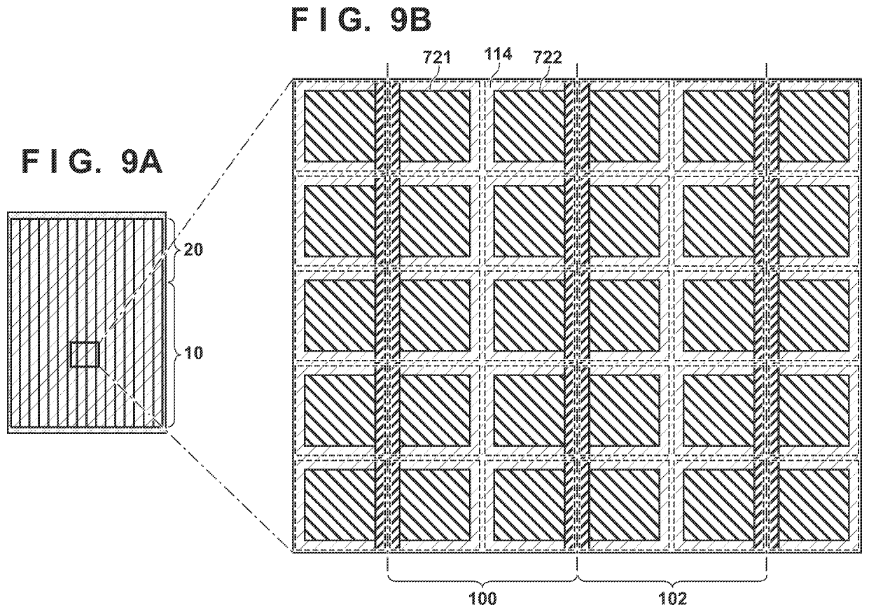

Another example of wirings, by which vertically arranged light emitting elements are individually driven by each two columns, is illustrated in FIG. 9A and FIG. 9B. In the example illustrated in FIG. 9B, the transparent conductive film 120 is stacked on the upper surface of the semiconductor layer 108 in the mesa structure of the first light emitting unit 100 and the upper surface of the semiconductor layer 108 in the mesa structure of the second light emitting unit 102. The transparent conductive film 120 between the first light emitting unit 100 and the second light emitting unit 102 is removed, and thus the first light emitting unit 100 and the second light emitting unit 102 are electrically separated from each other. The first drive wiring 114 is surrounding, without having an annular shape, three sides of the periphery of the light output portion 721 and three sides of the periphery of the light output portion 722. In addition, the first drive wiring 114 is in electrical contact with the upper surface of the semiconductor layer 108 of the first light emitting unit 100 via the opening formed in the third insulating film 122 and the opening formed in the first insulating film 112, similarly to the configuration illustrated in FIG. 7B and FIG. 8. Here, the drive wiring and the upper surface of the semiconductor layer 108 in the mesa structure may be brought into electrical contact with each other by providing openings around the light output portion similarly to the first embodiment. In such a case, the light output portions 718 connected by the insulating film may be provided with openings except for a part of the periphery around the light output portion. The openings 119 may be provided surrounding a part of the light output portion, as illustrated in FIG. 1B.

When the configuration illustrated in FIG. 7A and FIG. 7B and the configuration illustrated in FIG. 9A and FIG. 9B are compared, difference is that the current is supplied to all the VCSEL elements by only one wiring disposed between the light emitting element having the mesa structure in the configuration illustrated in FIG. 9A and FIG. 9B. In the configuration illustrated in FIG. 9A and FIG. 9B, maximum current density allowed to flow in the first drive wiring 114 is lower than the configuration illustrated in FIG. 7A and FIG. 7B. By employing the configuration illustrated in FIG. 7A and FIG. 7B, a larger amount of current is allowed to flow, and as a result, the density of optical power can be increased.

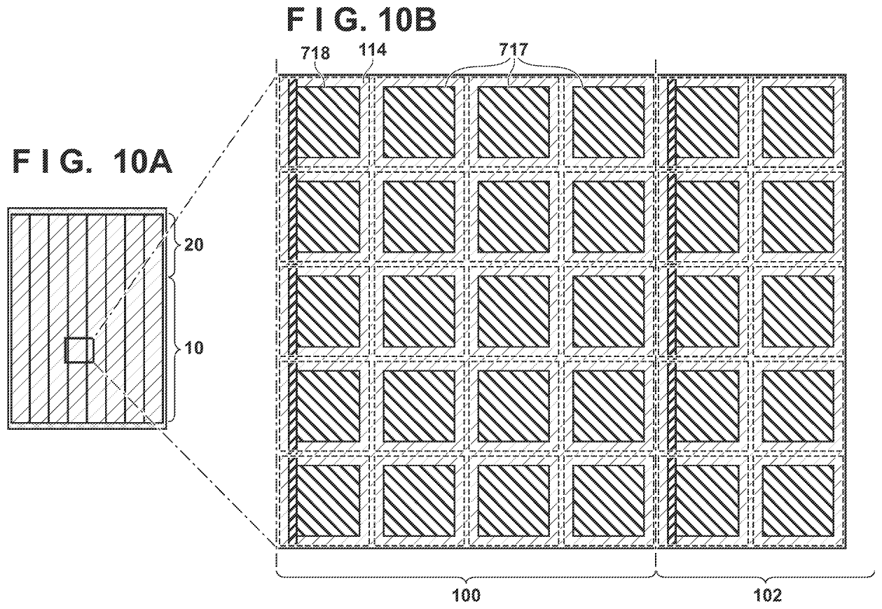

FIG. 10A and FIG. 10B illustrate a case in which number of columns of VCSEL elements to be simultaneously driven is four columns. When the number of columns is increased as the case of FIG. 10A and FIG. 10B, it is preferable to configure such that the first light emitting unit 100 includes a plurality of light output portions 717 each annularly surrounded by the first drive wiring 114 and a light output portion in which a part of the first drive wiring 114 is disconnected and a plurality of light output portions 718 are connected to each other. Also in the aforementioned case, the transparent conductive film 120 between the neighboring first light emitting unit 100 and the second light emitting unit 102 is removed, and thus the first light emitting unit 100 and the second light emitting unit 102 are electrically separated from each other, similarly to the example illustrated in FIG. 9. By employing the aforementioned configuration, the first drive wiring 114 can drive the light emitting elements arranged in four columns in the first light emitting unit 100. In addition, the drive wiring is arranged extending between the mesa structures, and thus the cross-sectional area of the drive wiring can be increased, whereby the density of optical power may be improved.

### Fourth Embodiment

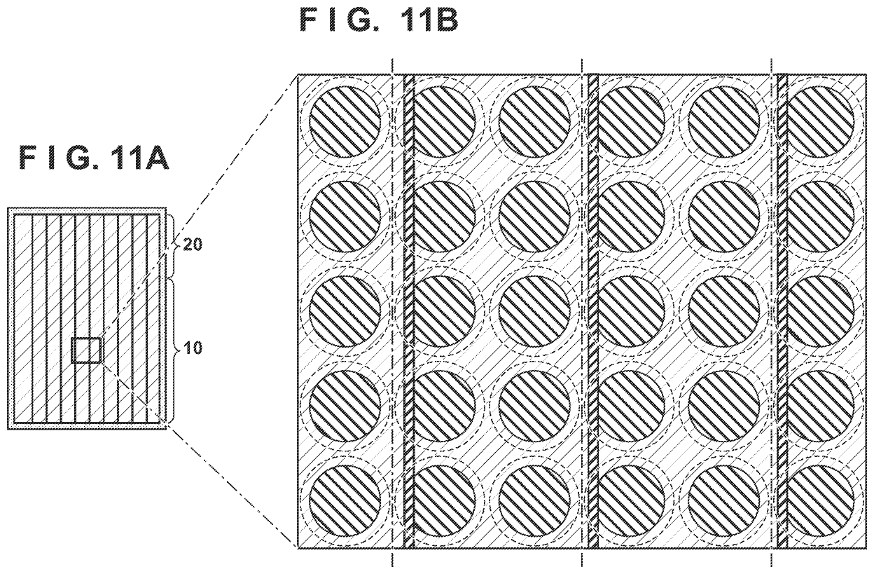

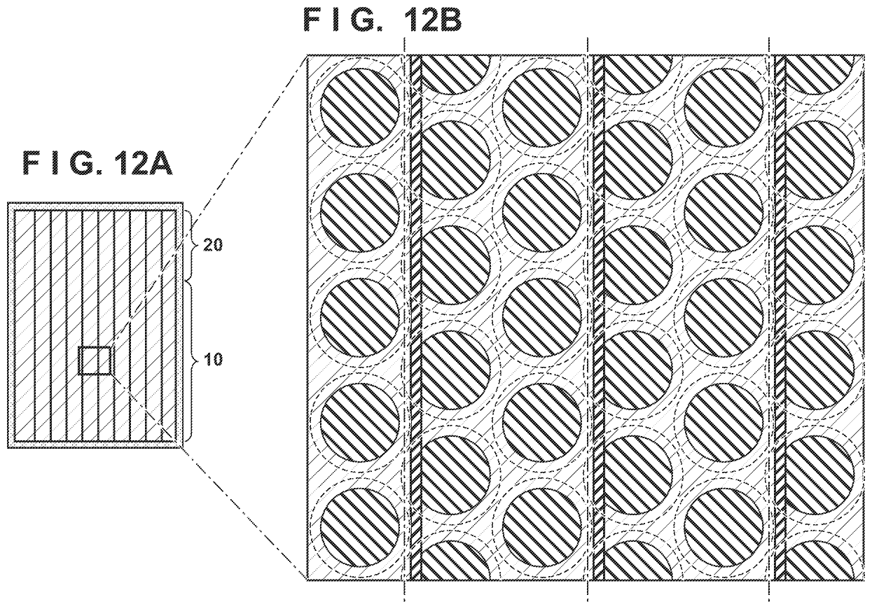

Although the light emitting element having the mesa structure described in the first embodiment to the third embodiment have a rectangular light emitting region, the light emitting region may be a circular light emitting region as illustrated in FIG. 11A and FIG. 11B. The circular light emitting region allows the light emitting elements having the mesa structure to be more densely arranged as illustrated in FIG. 12A and FIG. 12B, which is suitable for increasing the density of optical power. Here, as in the circular mesa structure described in FIG. 11A and FIG. 11B or FIG. 12A and FIG. 12B, the cross-sectional area of the drive wiring can be increased and the density of the optical power can be improved by employing the configurations described in the first embodiment to the third embodiment as the structure of the drive wiring. Although a circular mesa structure is described in the present embodiment, a mesa structure of polygonal shape may also be employed.

The present invention is not limited to the above embodiments and various changes and modifications can be made within the spirit and scope of the present invention. Therefore, to apprise the public of the scope of the present invention, the following claims are made.

According to the present invention, it is possible to provide an advantageous technology for driving a light emitting apparatus including a plurality of light emitting units, in which a plurality of light emitting elements are arranged, to emit light.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-070433, filed Apr. 21, 2023, which is hereby incorporated by reference herein in its entirety.

What is claimed is:

1. A light emitting apparatus comprising: a first light emitting unit and a second light emitting unit; and a first drive wiring configured to drive the first light emitting unit and a second drive wiring configured to drive the second light emitting unit, wherein
a plurality of light emitting elements having mesa structure of a compound semiconductor is arranged in the first light emitting unit and the second light emitting unit,
the first drive wiring is in electrical contact with an upper surface of the mesa structure of the compound semiconductor in the first light emitting unit, and the second drive wiring is in electrical contact with an upper surface of the mesa structure of the compound semiconductor in the second light emitting unit,
the first drive wiring extends above the upper surface of the mesa structure of the compound semiconductor in the second light emitting unit, and
the upper surface of the mesa structure of the compound semiconductor in the second light emitting unit and the first drive wiring are electrically insulated by an insulating film arranged between the upper surface of the mesa structure of the compound semiconductor in the second light emitting unit and the first drive wiring.

2. A light emitting apparatus comprising: a first light emitting unit and a second light emitting unit; and a first drive wiring configured to drive the first light emitting unit and a second drive wiring configured to drive the second light emitting unit, wherein
a plurality of light emitting elements having mesa structure of a compound semiconductor is arranged in the first light emitting unit and the second light emitting unit,
a transparent conductive film is arranged on an upper surface of the mesa structure of the compound semiconductor constituting the mesa structure,
the first drive wiring is in electrical contact with the transparent conductive film of the first light emitting unit, and the second drive wiring is in electrical contact with the transparent conductive film of the second light emitting unit, and
the first drive wiring extends above the transparent conductive film of the second light emitting unit, and the transparent conductive film of the second light emitting unit and the first drive wiring are electrically insulated by an insulating film arranged between the transparent conductive film of the second light emitting unit and the first drive wiring.

3. The light emitting apparatus according to claim 2, wherein the light emitting apparatus includes a light emitting unit in which a transparent conductive film is not arranged between the first light emitting unit and the second light emitting unit.

4. The light emitting apparatus according to claim 2, wherein the transparent conductive film is made of indium tin oxide (ITO)

5. The light emitting apparatus according to claim 1, wherein the first light emitting unit includes a plurality of light output portions partially surrounded by the first drive wiring.

6. The light emitting apparatus according to claim 1, wherein the first light emitting unit includes a plurality of light output portions surrounded by the first drive wiring.

7. The light emitting apparatus according to claim 1, wherein the first drive wiring and the second drive wiring are insulated from each other by the insulating film.

8. The light emitting apparatus according to claim 1, wherein the first drive wiring is arranged extending across between the first light emitting unit and the second light emitting unit.

9. The light emitting apparatus according to claim 1, wherein the first drive wiring and the second drive wiring are separated from each other by a distance equal to or less than a quarter of an interval by which the plurality of light emitting elements are arranged.

10. The light emitting apparatus according to claim 9, wherein the distance is equal to or less than 10 μm.

11. The light emitting apparatus according to claim 1, wherein a terminal pad is arranged in the light emitting apparatus.

12. The light emitting apparatus according to claim 1, wherein each of the plurality of light emitting elements are arranged at a constant interval.

13. The light emitting apparatus according to claim 1, wherein the first light emitting unit and the second light emitting unit are arranged alongside each other.

14. The light emitting apparatus according to claim 2, wherein the first light emitting unit includes a plurality of light output portions partially surrounded by the first drive wiring.

15. The light emitting apparatus according to claim 2, wherein the first light emitting unit includes a plurality of light output portions surrounded by the first drive wiring.

16. The light emitting apparatus according to claim 2, wherein the first drive wiring and the second drive wiring are insulated from each other by the insulating film.

17. The light emitting apparatus according to claim 2, wherein the first drive wiring is arranged extending across between the first light emitting unit and the second light emitting unit.

18. The light emitting apparatus according to claim 2, wherein the first drive wiring and the second drive wiring are separated from each other by a distance equal to or less than a quarter of an interval by which the plurality of light emitting elements are arranged.

19. The light emitting apparatus according to claim 18, wherein the distance is equal to or less than 10 μm.

20. The light emitting apparatus according to claim 2, wherein a terminal pad is arranged in the light emitting apparatus.

21. The light emitting apparatus according to claim 2, wherein each of the plurality of light emitting elements are arranged at a constant interval.

22. The light emitting apparatus according to claim 2, wherein the first light emitting unit and the second light emitting unit are arranged alongside each other.
